(19) United States
(12) Patent Application Publication
(10) Pub. No.: US 2026/0291447 A1
(43) Pub. Date: Sep. 24, 2026

(54) ZERO-COMMON-MODE MODULATION WITH DIGITAL FEEDBACK TO DAMP COMMON-MODE RESONANCE AND SUPPRESS CROSS-OVER DISTORTION

(71) Applicant: Monolithic Power Systems, Inc., Kirkland, WA (US)

(72) Inventors: Timo Adrianus Fake VAN DOESUM, Enschede (NL); Christiaan Egidius LOKIN, Enschede (NL); Daniel SCHINKEL, Enschede (NL); Olaf Robin Christiaan VAN DER MEER, Enschede (NL)

(21) Appl. No.: 19/478,562

(22) PCT Filed: Mar. 28, 2024
(86) PCT No.: PCT/NL2024/050157

§ 371 Date: Oct. 24, 2025

(30) Foreign Application Priority Data
Apr. 26, 2023 (NL) 2034708

(51) Int. Cl. H03F 1/34; H03F 3/187; H03F 3/217; H04R 3/00

(52) U.S. Cl. CPC H03F 1/342; H03F 3/187; H03F 3/2173; H04R 3/002; H03F 2200/03; H03F 2200/129; H03F 2200/165; H03F 2200/171; H03F 2200/351

(57) ABSTRACT

The present invention is in the field of basic electronic circuitry, in particular for an audio amplifier, more in particular a class-D amplifier, such as for use in a digital audio converter and digital amplifier controller, a chip comprising said audio amplifier, and a device comprising said audio amplifier or said chip

### RELATED APPLICATIONS

The present application claims the benefit of priority from Dutch Patent Applications NL2034708, filed on Apr. 26, 2023, in the name of Axign IP B. V., Netherlands.

The entire contents of the above-referenced application and of all priority documents as referenced in any present or future Application Data Sheet filed herewith are hereby incorporated by reference for all purposes.

### FIELD OF THE INVENTION

The present invention is in the field of basic electronic circuitry, in particular for an audio amplifier, more in particular a class-D amplifier, such as for use in a digital audio converter and digital amplifier controller, a chip comprising said audio amplifier, and a device comprising said audio amplifier or said chip.

### BACKGROUND OF THE INVENTION

An audio power amplifier comprises basic electronic circuitry that amplifies low-power electronic audio signals that enter the circuitry, to a high enough power for driving a loudspeaker. Audio power amplifiers find many applications. The audio amplifier may be combined in a chain of electronic components or electronic circuits, each performing an individual task or contributing to a common task. Basically any audio signal can be provided to the power amplifier, as is commonly done. The output power of the audio amplifier may be from a few watts to tens or hundreds of watts, and sometimes even a multitude thereof. Power amplifiers are typically integrated in a (final) product or integrated circuit.

Design parameters for audio power amplifiers are amongst others frequency response, gain, noise, and distortion, which parameters are typically interdependent.

A Class-D amplifier is typically used in modern consumer electronics audio products, bass amplifiers and sound reinforcement system gear. Amplifiers may comprise filters, pre-amplifiers, power output stages and the like. An audio filter is typically a frequency depend-ent circuit. It is designed to operate in a specific audio frequency range. It is noted that a human hearing range is commonly considered to run from 20 to 20,000 Hz. There is however a considerable variation between individuals, especially at high frequencies. Also, typically there is a gradual loss of sensitivity to higher frequencies with age. In addition, sensitivity to specific frequencies may also vary with said frequency. The audio frequency range typically used in audio amplifiers therefore runs from about 20 Hz to 20 kHz, and sometimes to 40 kHz or even 80 kHz. Audio filters are designed to amplify, pass, or attenuate specific frequency ranges. Many types of filters exist, for instance low-pass filters, high-pass filters, band pass filters, all-pass filters affecting a phase of a given frequency component, a magnitude, etc.

In battery operated amplifiers, inducing low power losses are key to extend battery play time (and/or reduce battery cost). In AD/BD modulated Class-D amplifiers, losses at low output powers are often dominated by switching losses and by (conduction/magnetic) inductor ripple losses.

In DOI:10.1109/JSSC.2017.2731812 Schinkel et al. recite a 5×80 W class-D audio power amplifier for automotive applications is presented. The amplifier is implemented in a 140-nm bipolar CMOS DMOS SOI. Configurable digital-loop filters can compensate for a range of LC output filters and their high loop gain (>50 dB between 20 Hz and 20 kHz) suppresses non-idealities of the output filter and enables low-cost output filter components. Key elements are the integrated low-latency ΔΣ analog to digital converters (ADCs) which digit-ize the output signals directly at the speaker load, after the output filter. The ADCs use filter-ing finite impulse response digital to analog converters in their feedback path to create an in-put-output transfer with a negative group delay at low frequencies. The ADCs have 116-dBA DR and −108 dB total harmonic distortion (THD). The bridge-tied load amplifier supports multiphase pulse-width modulation for lower electromagnetic interference. It operates with supplies from 6 to 25 V and with loads down to 1 Ω and achieves 19-μV idle noise (Awtd) and 0.004% THD+N. US 2019/081621 A1 recites a programmable pulse width modulator (PWM) controller comprising filters and a mixer, such as for use in a digital audio converter and digital amplifier controller, a chip comprising said PWM controller, a device comprising said PWM controller or said chip, as well as uses thereof.

It is an objective of the present invention to overcome disadvantages of the prior art audio amplifiers without jeopardizing functionality and advantages.

### SUMMARY OF THE INVENTION

The present invention relates in a first aspect to a digital control loop (10) for a signal amplifier, such as an audio amplifier, in particular for a Class D amplifier, comprising-at least one input (21,31) configured to receive a digital electronic signal, in particular a single ended input signal that will end up as a differential-mode output signal, the at least one input configured to provide input to at least one first adder (41), wherein the at least one first adder is configured to provide input to-at least one differential-mode loop filter (DMLF)(20), wherein the at least one DMLF is configured to provide input to at least one second adder (42) and to at least one third adder (43), wherein the second adder is configured to provide input to at least one first Pulse Width Modulator (PWM)(61), the first PWM configured to provide output, wherein the third adder is configured to provide input to at least one second Pulse Width Modulator (PWM)(62), the second PWM configured to provide output, at least one common-mode loop filter (CMLF)(30), wherein the CMLF is configured to provide input to the at least one second adder and to the at least one third adder, and at least one Low Latency Analog to Digital Converter (LLADC)(70), wherein the at least one LLADC is configured to provide input to the at least one first adder and to provide input to an at least one fourth adder (44) and/or the at least one CMLF, and configured to receive input from at least one output filter, in particular to receive analog input, at least one differential clip controller (DCC) (50), the at least one DCC con-figured to receive input from the at least one second adder (42) and the at least one third adder (43) and to provide output to the at least one first Pulse Width Modulator (PWM) and the at least one second Pulse Width Modulator (PWM), wherein the digital control loop is configured to provide substantially zero-common-mode modulation. Differential signaling typically refers to a technique transmitting electrically information using two complementary signals. The technique sends the same electrical signal as a differential pair of signals, each in its own conductor. The pair of conductors can be wires in a twisted-pair or ribbon cable or traces on a printed circuit board. Electrically, the two conductors typically carry voltage signals which are equal in magnitude, but of opposite polarity. A receiving circuit responds to the difference between the two signals, which results in a signal with a magnitude twice as large. Differential signaling in itself typically does not make a line balanced, nor does noise rejection in balanced circuits require differential signaling. A common-mode signal typically refers to the voltage being common to both input terminals of an electrical device. In most electrical circuits the signal is transferred by a differential voltage between two conductors. If the voltages on these conductors are U1 and U2, the common-mode signal is the half-sum of the voltages. When referenced to the local common or ground, a common-mode signal appears on both lines of a two-wire cable, in phase and with equal ampli-tudes. Technically, a common-mode voltage is one-half the vector sum of the voltages from each conductor of a balanced circuit to local ground or common. Such signals can arise from various sources. Noise induced into a cable, or transmitted from a cable, usually occurs in the common mode, as the same signal tends to be picked up by both conductors in a two-wire cable. Likewise, RF noise transmitted from a cable tends to emanate from both conductors. Elimination of common-mode signals on cables entering or leaving electronic equipment is typically important to ensure electro-magnetic compatibility. The present differential-mode loop controls the differential signal on the output, these are typically two complementary signals, however, in an exemplary embodiment, one terminal is at ground and the other terminal carries the signal. The present input is used to create a differential output. In this aspect, for better understanding, a differential electronic signal is considered to always be a signal pair, namely a negative and positive variant of the signal for noise reduction after transmission over cables. BD modulation relates to a modulation scheme developed to greatly reduce the output filter. The modulation scheme minimizes switching current. Zero-common-mode modulation is considered to be a form of BD modulation, where the common-mode component is (close to) zero when there is no differential component and is kept to a minimum when there is a differential component. This results in a very efficient switching scheme, in particular in Class-D audio amplifiers, as only one half-bridge is switching at a time. The term “zero-common-mode modulation” is used to indicate a keep the common mode close to or at zero I idle mode, and to modulate when providing output (see also figures). So, very precisely, it relates more to a low-common-mode modulation, close to zero, with further a power efficient PWM, a modulation with zero idle common-mode, etc. A prior art problem with such a modulation scheme is the high common-mode excursions at double the signal frequency, which leads to LC-filter resonance. This resonance causes extra dissipation and interferes with the differential-mode audio signal. The present invention provides a (digital) common-mode loop, which e.g. suppresses such resonances without the use of extra (dissipating) analog components. Next to this common-mode loop, a (digital) differential-mode loop is provided, which allows for instance a high loop gain in a high band-width (covering the whole audio band from 0 Hz-20 kHz). This high-order differential-mode loop may be used to suppress cross-over distortion, which may occur when one half-bridge takes over from the other bridge halve. At a zero crossing of e.g. a sinewave, the power stage may need to make very small pulses. Due to typical imperfect switching, these small pulses are often distorted (either longer/shorter/lower than ex-pected). This may lead to distortion in these zero crossings. The present DM loop suppresses this. Using the present zero-common-mode modulation configuration, the inductor current ripple is reduced close to zero and is therefore considered to be negligible, in particular in idle mode. Also switching losses are reduced, as only one half bridge is switching at a time. This is considered specifically relevant for non-zero signals. Also, it often incurs a two-fold switching frequency for an effective number of decision moments, which under-mines this point. Pulse-skipping under the idle condition may play a role in the switching losses reduction. Power consumption in audio amplifiers is therewith reduced, especially at lower output powers. Also common-mode LC resonance in Class-D audio amplifiers using zero-common-mode modulation is reduced, by using the present CMLF. And cross-over distortion due to zero-common-mode modulation is also reduced by using the present DMLF. Cross-over distortion is reduced by about 60 dB, and/or by about a factor 1000 in amplitude. Common-mode ringing is reduced by about 20 dB, and/or by a factor of about 10 in amplitude. The LLADC low latency is preferably one clock cycle, hence typically within 50 nsec. This provides the audio processor with sufficient time to process signals. Typically feedback may be provided by the processor within 20 ADC clock cycles, and preferably within 10 ADC clock cycles, such as within 5 clock cycles. Such is considered very sophisticated.

In a second aspect the present invention relates to an audio amplifier, in particular a class-D amplifier, comprising at least one digital control loop according to the invention.

In a third aspect the present invention relates to an integrated circuit comprising the audio amplifier or the at least one digital control loop according to the invention.

In a fourth aspect the present invention relates to a product comprising at least one digital control loop according to the invention, or an audio amplifier according to the invention, in particular wherein the product is an audio product, more in particular wherein the product is selected from a portable speaker, from a battery operated speaker, from a mains operated heatsink-less amplifier, in particular a high power heatsink-less amplifier, from an electrical motor, and from a mains operated heatsink-less active speaker, in particular from a high power heatsink-less active speaker.

There are various applications of the present invention that may be considered. For instance, portable speakers, battery operated speakers, mains operated (high power) heatsink-less amplifiers, and mains operated (high power) heatsink-less active speakers.

Thereby the present invention provides a solution to one or more of the above men-tioned problems.

Advantages of the present description are detailed throughout the description.

### DETAILED DESCRIPTION OF THE INVENTION

The present invention relates in a first aspect to a digital control loop (10) for an audio amplifier, in particular for a Class D amplifier,

In an exemplary embodiment of the present digital control loop the at least one LLADC is configured to receive input from at least two terminals of an audio output filter (92).

In an exemplary embodiment of the present digital control loop the at least one first adder is configured to subtract LLADC input.

In an exemplary embodiment of the present digital control loop the at least one second adder is configured to add DMLF input and CMLF input.

In an exemplary embodiment of the present digital control loop the at least one third adder is configured to add CMLF input and to subtract DMLF input.

In an exemplary embodiment of the present digital control loop the digital control loop is configured to operate at an output power stage operating voltage of −100-+100 V, in particular −50-+50 V, and/or wherein the digital control loop is configured to operate at a voltage of 0.5-5V, such as 1-2V, that is configured to control the power stage with said voltage of 0.5-5V.

The present digital control loop is configured to provide substantially zero-common-mode modulation.

In an exemplary embodiment of the present digital control loop the at least one LLADC is configured to comprise at least two resistors in electronic contact with a respective input of the at least one LLADC, or wherein the at least one LLADC is configured to receive input from at least two resistors in electronic contact with a respective input of the at least one LLADC, in particular wherein each of the at least two resistors is a V-to-I conversion resistor. This provides an advantage of scaling output power and noise, while keeping the dynamic range of the LLADC optimal. Lower required output power means lower resistor value and thus lower noise.

In an exemplary embodiment of the present digital control loop the at least two resistors each individually have a resistance of 100 Ω-50 kΩ, in particular 1 kΩ-30 kΩ, more in particular 2 kΩ-15 kΩ, such as 3 kΩ-7 kΩ.

In an exemplary embodiment of the present digital control loop the at least one LLADC is configured to operate at a current of 1-100 mA, in particular 2-50 mA, more in particular 3-10 mA.

In an exemplary embodiment of the present digital control loop the at least one LLADC each individually is configured to provide input to at least one fourth adder (44), wherein the at least one fourth adder is configured to add LLADC output and at least one second input (31), in particular Common-mode input, and to provide input to the at least one CMLF. Such provides suppression of the common-mode LC resonance, in order to prevent excessive resonance of the LC tank, which would in turn lead to instability in the differential-mode loop and increased losses in the LC output filter. Also an input may go to 0V or its digital equivalent.

In an exemplary embodiment of the present digital control loop at least one of the at least one first PWM and the at least one second PWM each individually is configured to be connected to a power stage (91), and wherein the power stage is configured to increase the output voltage, in particular to increase the output voltage with a factor 1-2⁷ with respect to the output voltage of the at least one PWM. An example thereof is given in FIGS. 3 and 4.

In an exemplary embodiment the present digital control loop comprises at least one digital input to DMLF (21) configured to provide input to the at least one first adder (41), and at least one digital input to CMLF (31) configured to provide input to at least one fourth adder (44), the at least one fourth adder configured to provide input to the at least one CMLF. For example, the common mode input is configured to provide a zero as input, or is configured to provide an absolute value of a differential mode signal as input, or a quadratic value of a differential mode signal as input, that is a representation of an envelope of the differential mode signal.

The present digital control loop comprises at least one differential clip controller (DCC) (50), the at least one DCC configured to receive input from the at least one second adder (42) and the at least one third adder (43) and to provide output to the at least one first Pulse Width Modulator (PWM) and the at least one second Pulse Width Modulator (PWM).

In an exemplary embodiment of the present digital control loop the DCC comprises at least one first DCC limiter (52) and at least one second DCC limiter (53), wherein each limiter individually is configured to receive input from the at least one second adder and the at least one third adder (43), respectively, and at least four DCC adders (54a,b,c,d), wherein a first DCC adder (54a) is configured to receive input from the at least one second adder (42), and from the first DCC limiter (52), and to subtract the output from the first DCC limiter (52) from the output of the at least one second adder (42), and to provide output to a fourth DCC adder (54d), and wherein a second DCC adder (54b) is configured to receive input from the first DCC limiter (52) and from a third DCC adder (54c), and to subtract input from the third DCC adder (54c) from the output of the first DCC limiter (52), and to provide output to the at least one first PWM (61), wherein a third DCC adder (54c) is configured to receive input from the at least one third adder (43), and from the second DCC limiter (53), and to subtract the output from the at least one second DCC limiter (53) from the output of the at least one third adder (43), and to provide output to the second DCC adder (54b), and wherein the fourth DCC adder (52d) is configured to receive input from the second DCC limiter (53) and from the first DCC adder (54a), and to subtract output from the first DCC adder (54a) from the output of the second DCC limiter (53), and to provide output to the at least one second PWM (62), in particular wherein the DCC is configured to preserve a differential signal when either of the limiters limit the signal. An example thereof is given in FIG. 3.

In an exemplary embodiment the present audio amplifier further comprises at least one power stage configured to receive input from the at least one first PWM and from the at least one second PWM.

In an exemplary embodiment the present audio amplifier further comprises an output stage, the output stage comprising an output filter configured to receive input from the at least one power stage, configured to provide output to a speaker, and configured to provide input to the LLADC.

The invention although described in detailed explanatory context may be best understood in conjunction with the accompanying examples and figures.

### SUMMARY OF FIGURES

FIGS. 1-2, 3a-d, 4a-d, 5a-d, 6a-d, 7a-d, 8a-f, 9-12, and 13a,b provide examples of the present invention.

### DETAILED DESCRIPTION OF FIGURES

The figures are of an exemplary nature. Elements of the figures may be combined.

In the figures:
10 digital control loop
20 differential-mode loop filter (DMLF)
21 digital input to DMLF
30 common-mode loop filter (CMLF)
31 digital input to CMLF
41 first adder
42 second adder
43 third adder
44 fourth adder
50 Differential clip controller
52 first DCC limiter
53 second DCC limiter
54a first DCC adder
54b second DCC adder
54c third DCC adder
54d fourth DCC adder
61 first Pulse Width Modulator (PWM)
62 second Pulse Width Modulator (PWM)
70 Low Latency Analog to Digital Converter [details]
71 Common-mode LLADC output
72 Differential-mode LLADC output
80 V-to-I conversion resistor
91 power stage
92 Output filter
93 (speaker) load

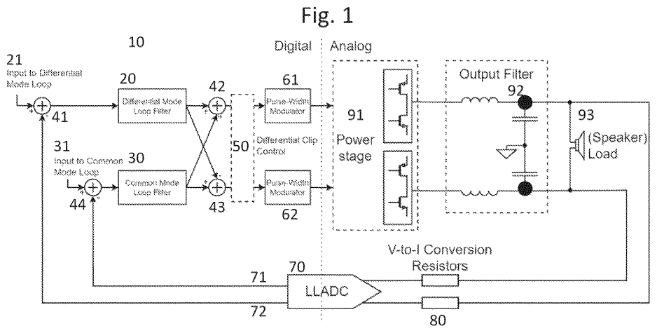

FIG. 1 describes the different elements in the system. The system consists of a digital differential-mode loop and a common-mode loop.

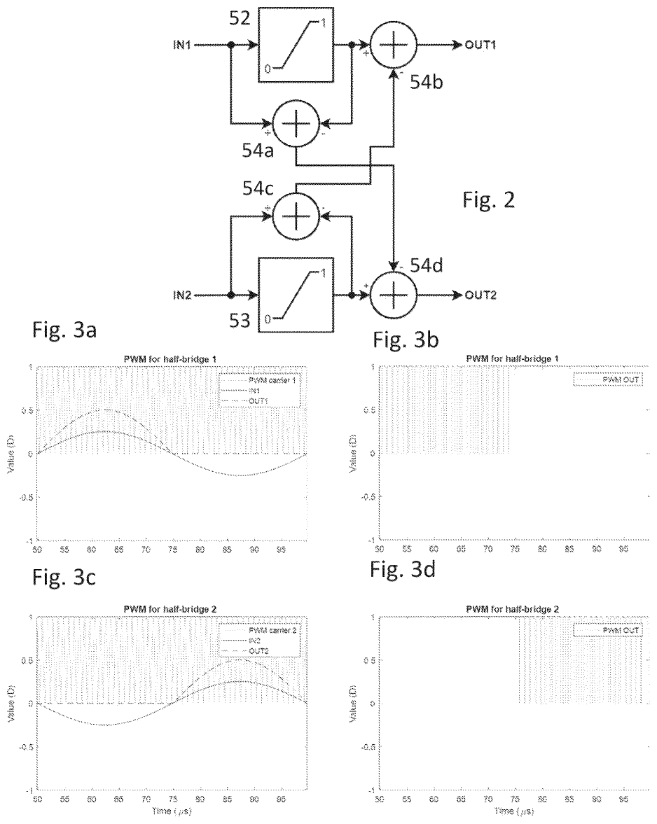

FIG. 2 shows a possible implementation of differential clip control. This implementation gives priority to the differential-mode signal, to ensure that the differential signal is preserved in case either input signal is limited.

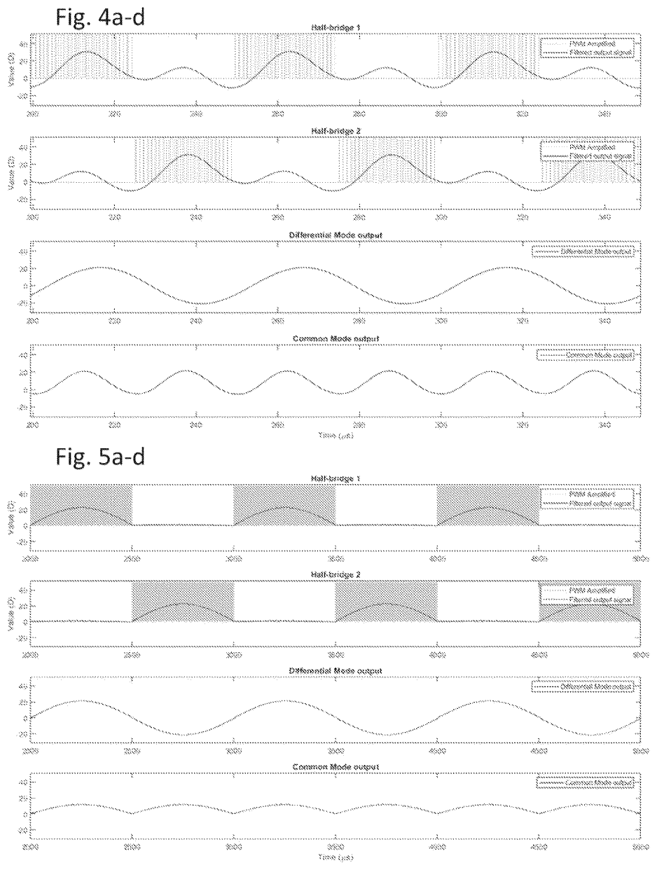

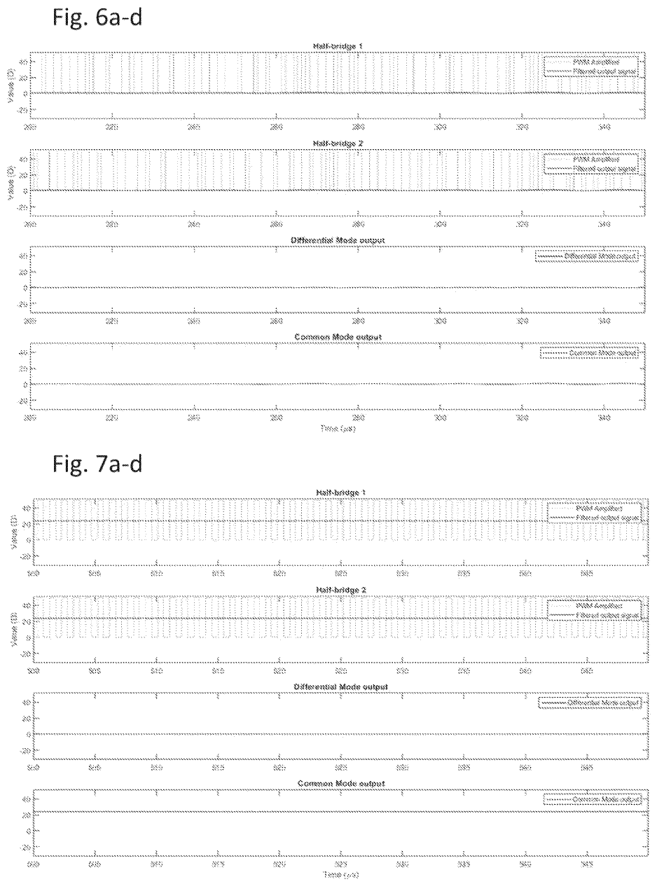

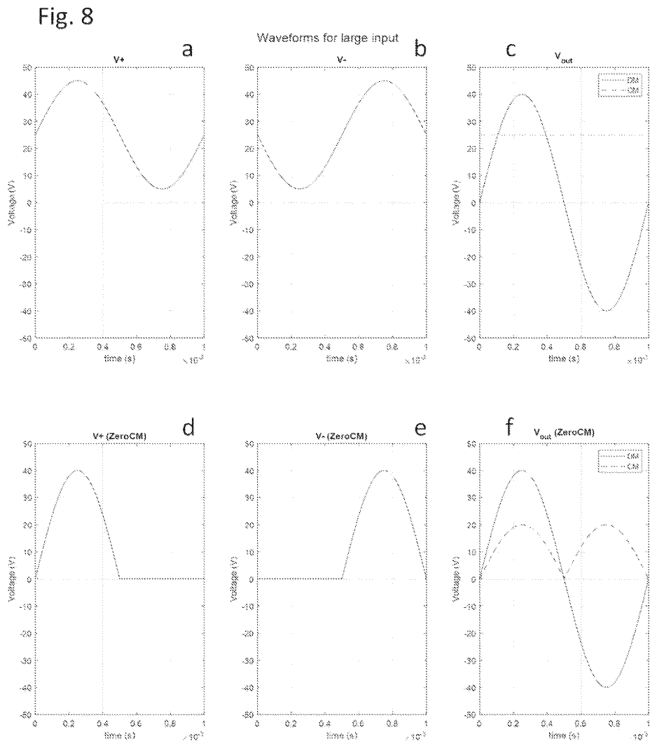

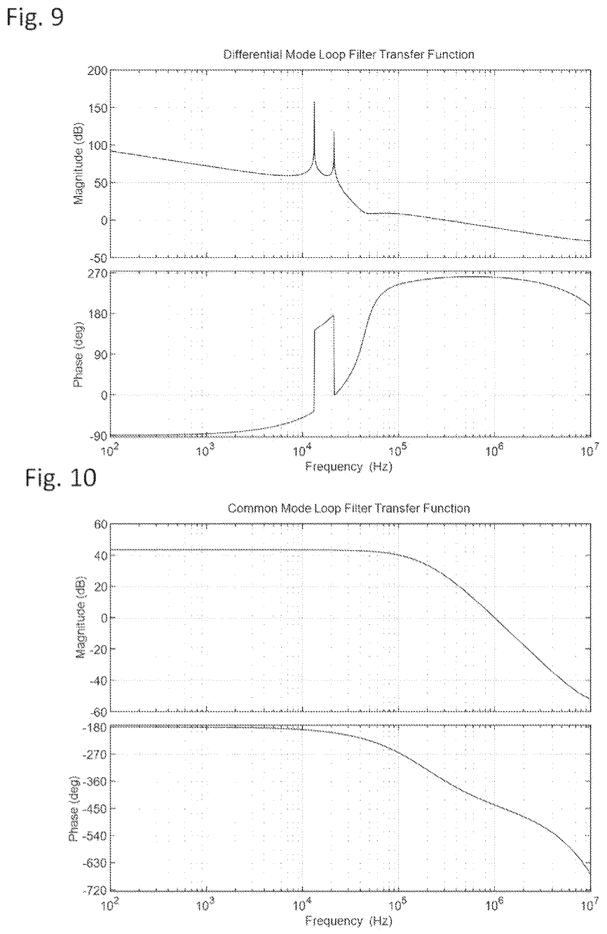

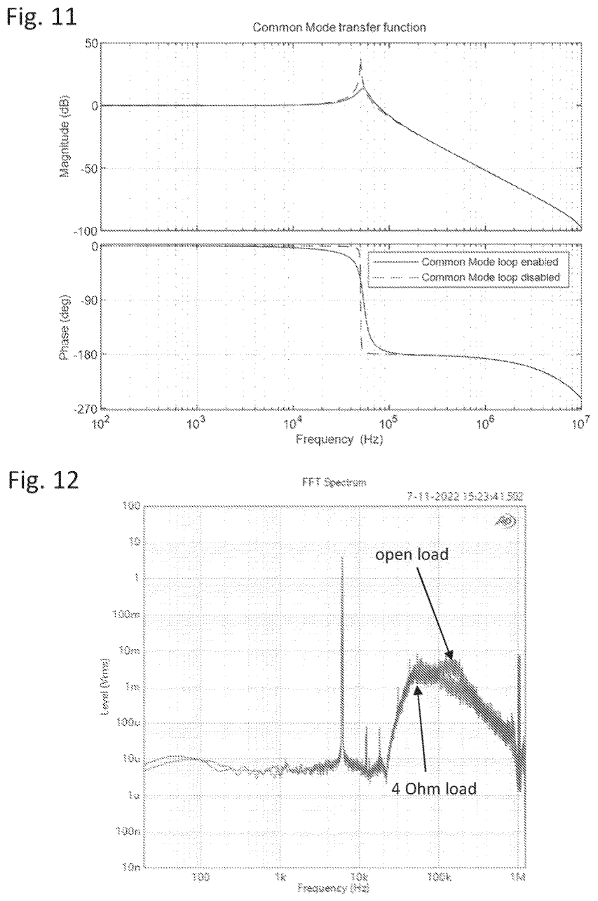

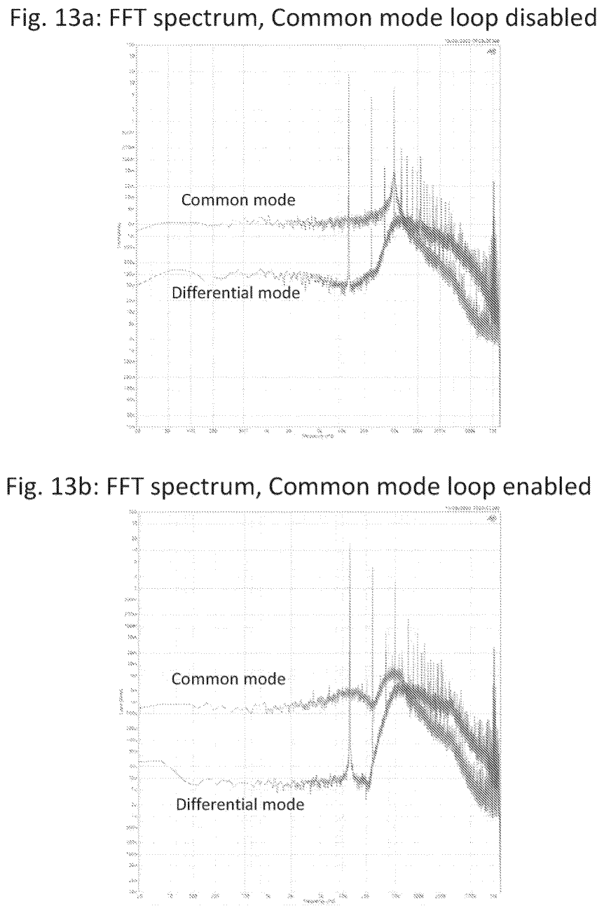

FIG. 3 shows the PWM carriers of the first and second PWM and inputs and outputs from the differential clip control and the resulting PWM waveforms from the first and second PWM. These PWM waveforms result from comparing the PWM carrier of the first PWM with the first output of the DCC and comparing the PWM carrier of the second PWM with the second output of the DCC. These PWM waveforms are the outputs of the first and second PWM and these are amplified by the power stage. This example uses a 20 kHz sinewave as input signal and a 1024 kHz PWM carrier frequency.

FIG. 4 shows the amplified PWM waveforms and the filtered PWM waveform (FIG. 4a and FIG. 4b) and the resulting differential-mode output (FIG. 4c) and common-mode output (FIG. 4d). This example uses the same 20 kHz sinewave as input signal and a 1024 kHz PWM carrier frequency. The power supply voltage for the power stage is 50V in this example. The output filter inductors used in this example are 10 μH, the output filter capacitors are 1 μF, the differential (speaker) load is 4.5 Ohm.

FIG. 5 shows the same but with a 1 kHz input signal instead of 20 kHz. This clearly shows only one half-bridge is switching at any moment in time. This also illustrates the dis-advantage of this modulation scheme; in the zero crossing of the sinewave one half-bridge takes over from the other half-bridge. At that moment, very small pulses need to be made by the power stage to accurately follow the input signal. Small deviations in pulse width lead to distortion of the output signal.

FIG. 6 shows the same signals as in FIGS. 4 and 5, but in idle situation (no differential input/output signal). This shows the advantage with respect to the usual BD modulation which switches at 50% duty cycle in idle (FIG. 7). This leads to ripple current in the inductor which leads to losses. Zero-common-mode modulation only makes very small pulses which means the inductor current ripple is almost zero. This reduces the losses associated with ripple current in the inductor and power stage to almost zero. Furthermore, only one half-bridge switches at a time, reducing the effective switching frequency per half-bridge by a factor 2. This decreases all losses related to switching the power stage by a factor 2. This also shows that both differential and common output are substantially zero in idle.

FIG. 7, relating at least partly to a prior art embodiment, shows the same situation as FIG. 6, but for BD modulation. This shows that both half-bridges are switching at the same time and at 50% duty cycle in idle. The differential output is zero, but the common-mode output is 25V in this example (50% of the supply voltage of the power stage). This leads to significant ripple current in the output filter inductors and related losses in the inductors and output stage.

FIG. 8a-c: BD modulated output waveforms; FIG. 8d-f: Zero-common-mode modulated waveforms. V+ is one side of the speaker load, V− is the other side of the speaker load as seen in FIG. 1.

FIG. 9 shows the transfer function of an example of a differential-mode loop filter with high gain in the 0-20 kHz band to suppress any distortion introduced in the DCC, power stage and LC output filter.

FIG. 10 shows the transfer function of an example of a common-mode loop filter. Together with the LC transfer and LLADC transfer this leads to a damped common-mode response.

FIG. 11 shows the common-mode transfer function from PWM to (speaker) output. The dashed line shows the situation without common-mode loop. The solid line shows the situation with common-mode loop enabled. This shows that the common-mode loop damps the common-mode resonance. The advantage of this damping is that harmonics of the input frequency do not get amplified by this high peak in the CM transfer. FIG. 13 further illustrates this.

FIG. 12 shows the measured differential-mode spectrum over the speaker load with zero-common-mode modulation. This shows the advantage of the high-order digital control loop with a loop filter transfer function as shown in FIG. 9. The spectrum shows low noise up to 20 kHz and low distortion of the input signal.

FIG. 13a-b show the measured common-mode and differential-mode spectra over the speaker load with zero-common-mode modulation. FIG. 13a shows the spectrum when the common-mode loop is disabled. FIG. 13b shows the spectrum when the common-mode loop is enabled. This shows that when the common-mode loop is disabled, the 4^{th} harmonic of the 12.25 kHz sinewave is amplified by the common-mode response of the LC filter. This leads to overloading in the differential-mode with increased noise over the speaker load as result. When the common-mode loop is enabled, this 4^{th} harmonic is not amplified and the differential-mode loop does not overload and keeps the noise over the speaker load much lower.

Details of the figures and advantages of the embodiments disclosed therein are given throughout the description.

1. A digital control loop for a signal amplifier, in particular for an audio amplifier, more in particular for a Class D amplifier, comprising
at least one input configured to receive a digital electronic signal, the at least one input configured to provide input to
at least one first adder, wherein the at least one first adder is configured to provide input to
at least one differential-mode loop filter (DMLF), wherein the at least one DMLF is configured to provide input to
at least one second adder and to at least one third adder,
wherein the second adder is configured to provide input to
at least one first Pulse Width Modulator (PWM), the first PWM con-figured to provide output,
wherein the third adder is configured to provide input to
at least one second Pulse Width Modulator (PWM), the second PWM configured to provide output,
at least one common-mode loop filter (CMLF), wherein the CMLF is configured to provide input to the at least one second adder and to the at least one third adder,
at least one Low Latency Analog to Digital Converter (LLADC), where-in the at least one LLADC is configured to provide input to the at least one first adder and to provide input to the at least one CMLF, and configured to receive input from at least one output filter, and
at least one differential clip controller (DCC), the at least one DCC con-figured to receive input from the at least one second adder and the at least one third adder and to provide output to the at least one first Pulse Width Modulator (PWM) and the at least one second Pulse Width Modulator (PWM),
wherein the digital control loop is configured to provide substantially zero-common-mode modulation.

2. The digital control loop for an audio amplifier according to claim 1, wherein the at least one LLADC is configured to receive input from at least two terminals of an audio output filter.

3. The digital control loop for an audio amplifier according to claim 1, wherein the at least one first adder is configured to subtract LLADC input.

4. The digital control loop for an audio amplifier according to claim 1, wherein the at least one second adder is configured to add DMLF input and CMLF input.

5. The digital control loop for an audio amplifier according to claim 1, wherein the at least one third adder is configured to add CMLF input and to subtract DMLF input.

6. The digital control loop for an audio amplifier according to claim 1, wherein the digital control loop is configured to operate at an output power stage operating voltage of −100-+100 V, in particular −50-+50 V, and/or wherein the digital control loop is config-ured to operate at a voltage of 0.5-5V.

7. The digital control loop for an audio amplifier according to claim 1 wherein the at least one LLADC is configured to comprise at least two resistors in electronic con-tact with a respective input of the at least one LLADC, or wherein the at least one LLADC is configured to receive input from at least two resistors in electronic contact with a respec-tive input of the at least one LLADC, wherein each of the at least two resistors is a V-to-I conversion resistor.

8. The digital control loop for an audio amplifier according to claim 7, wherein the at least two resistors each individually have a resistance of 100 Ω-50 kΩ.

9. The digital control loop for an audio amplifier according to claim 1, wherein the at least one LLADC is configured to operate at a current of 1-100 mA.

10. The digital control loop for an audio amplifier according to claim 1, wherein the at least one LLADC each individually is configured to provide input to at least one fourth adder, wherein the at least one fourth adder is configured to subtract LLADC output and at least one second input, and to provide input to the at least one CMLF.

11. The digital control loop for an audio amplifier according to claim 1, wherein at least one of the at least one first PWM and the at least one second PWM each individually is configured to be connected to a power stage, and wherein the power stage is con-figured to increase the output voltage.

12. The digital control loop for an audio amplifier according to claim 1, comprising at least one digital input to DMLF configured to provide input to the at least one first adder, and at least one digital input to CMLF configured to provide input to at least one fourth adder, the at least one fourth adder configured to provide input to the at least one CMLF.

13. The digital control loop for an audio amplifier according to claim 1, wherein the DCC comprises
at least one first limiter and
at least one second limiter, wherein each limiter individually is configured to receive input from the at least one second adder and the at least one third adder, respectively, and
at least four DCC adders,
wherein the first DCC adder is configured to receive input from the at least one second adder, and from the first DCC limiter, and to subtract the output from the first DCC limiter from the output of the at least one second adder, and to provide output to a fourth DCC adder, and
wherein the second DCC adder is configured to receive input from the first DCC limiter and from a third DCC adder, and to subtract output from the third DCC adder from the output of the first DCC limiter, and to provide output to the at least one first PWM,
wherein the third DCC adder is configured to receive input from the at least one third adder, and from the second DCC limiter, and to subtract the output of the second DCC limiter from the output of the at least one third adder, and to pro-vide output to the second DCC adder, and
wherein the fourth DCC adder is configured to receive input from the second DCC limiter and from the first DCC adder, and to subtract output from the first DCC adder from the output of the second DCC limiter, and to provide output to the at least one second PWM,
wherein the DCC is configured to preserve a differential signal when either of the limiters limit the signal.

14. An audio amplifier, in particular a class-D amplifier, comprising at least one digital control loop according to claim 1.

15. The audio amplifier according to claim 14, further comprising at least one power stage configured to receive input from the at least one first PWM and from the at least one second PWM.

16. The audio amplifier according to claim 14, further comprising an output stage, the output stage comprising an output filter configured to receive input from the at least one power stage, configured to provide output to a speaker, and configured to provide input to the at least one LLADC.

17. An integrated circuit comprising at least one digital control loop according to claim 1, or an audio amplifier according to claim 16.

18. A product comprising at least one digital control loop according to claim 1, or an audio amplifier according to claim 16, wherein the product is an audio product, wherein the product is selected from a portable speaker, from a battery operated speaker, from a mains operated heatsink-less amplifier, a high power heatsink-less amplifier, from an electrical motor, and from a mains operated heatsink-less active speaker, from a high power heatsink-less active speaker.

19. The digital control loop for an audio amplifier according to claim 10, wherein the at least one second input is Common-mode input.

20. The digital control loop for an audio amplifier according to claim 11, wherein the power stage is configured to increase the output voltage with a factor 1-2⁷ with respect to the output voltage of the at least one PWM.
